(19) United States
(12) Patent Application Publication
(10) Pub. No.: US 2025/0219610 A1
(43) Pub. Date: Jul. 3, 2025

(54) STRAINED PIEZOELECTRIC DEVICES FOR RADIOFREQUENCY RESONATORS AND FABRICATION METHODS THEREOF

(71) Applicant: Robert Bosch GmbH, Stuttgart (DE)

(72) Inventors: Mordechai Kornbluth, Brighton, MA (US); Sanjay Gopalan, Richardson, TX (US); Christoph Schelling, Stuttgart (DE); Simon Schneider, Karlsruhe (DE)

(21) Appl. No.: 18/400,615

(22) Filed: Dec. 29, 2023

(51) Int. Cl. H03H 9/02; H03H 3/02; H03H 9/17; H03H 9/56; H10N 30/00; H10N 30/079

(52) U.S. Cl. CPC H03H 9/02133; H03H 3/02; H03H 9/02031; H03H 9/171; H03H 9/176; H03H 9/562; H03H 9/564; H10N 30/079; H10N 30/708

(57) ABSTRACT

Disclosed are methods of fabrication and related piezoelectric devices comprising a piezoelectric layer with an induced compressive strain along a z-axis. The methods include formation of a stress layer on a bottom side of a wafer substrate, after deposition of the piezoelectric layer. Stress layer removal results in an induced compressive strain along the z-axis which increases the electromechanical coupling coefficient, and thereby piezoelectric performance. Related devices are also disclosed, including bulk acoustic wave (BAW) thin film resonators (FBAR), which are fabricated in accordance with the disclosed methods.

### TECHNICAL FIELD

The present disclosure relates to devices comprising piezoelectric elements and methods of fabricating said devices. More specifically, the disclosure relates to bulk acoustic wave (BAW) resonators comprising piezoelectric thin films.

### BACKGROUND

The advancement of modern wireless communication systems requires high-performance filters and frequency reference elements with high operation frequency, miniature size, and low cost. Bulk acoustic wave (BAW) resonators are well suited for mobile telecommunication systems operating at high frequencies from 0.5 to 10 GHz and have been intensively developed for the past 20 years. A BAW resonator typically consists of a layer of piezoelectric thin film sandwiched between two thin metal electrodes. When an alternating electrical voltage is applied between the two electrodes, the consequent electric field between the electrodes interacts with piezoelectric material to generate acoustic waves within the piezoelectric material.

Key parameters of a resonator include the frequency response, the quality factor (how much of the energy is kept and not dissipated), and ease of fabrication. A piezoelectric material is a material that couples mechanical strain and electric fields. Due to a polarizable non-symmetric atomic structure, an applied electric field will induce a mechanical strain, and conversely a mechanical strain will induce an electric field in the material. As noted above, in a BAW resonator, a microscale crystal is sandwiched by electrodes, where an incoming electromagnetic wave will create a voltage differential if it matches the resonance frequency of the resonator.

In a longitudinal resonator, the figure of merit is given by kₜ_{²}Q, where Q is the quality factor of the resonator, and kₜ_{²} is the intrinsic electromechanical coupling coefficient, which is

$$\frac{{e}_{33}^{2}}{{e}_{33}^{2} + {ϵ}_{33} {C}_{33}^{E}} .$$

These symbols relate the coupling between electric and stress fields and forces, as follows:

| Basic macroscopic | |
|---|---|
| equations | Description |
| \vec{σ} = Ĉ^{E} \vec{ε} − ê^{T} \vec{E} | Stress-strain relation (stiffness) including |
| | piezoelectric effect |
| \vec{D} = ê\vec{ε} + \hat{ϵ}\vec{E} | Displacement field, including piezoelectric effect |

where \vec{σ} is the stress, Ĉ^{E} is the stiffness tensor under constant electric field, \vec{ε} is the strain field, ê is the piezoelectric tensor, \vec{E} is the electric field, \vec{D} is the displacement field, and ê is the dielectric tensor.

One key material for piezoelectric resonators is wurtzite aluminum nitride (AlN). This can be formed as a (BAW) resonator, often as a thin film based acoustic wave resonator (FBAR). To reduce electromechanical losses to the substrate, different architectures are used, such as a membrane FBAR, air gap FBAR, and solidly mounted resonator (SMR).

Recent research shows that doping the AlN with scandium (Sc) forms Al₁₋ₓScₓN, which has shown to be an improved piezoelectric material. The scandium both lowers the stiffness (C) and raises the piezoelectric tensor (ê), both of which lead to a greater kₜ_{²} value.

One major challenge in using scandium alloy for AlN is that it is difficult to obtain a uniform distribution of the scandium alloy configuration at a high Sc content because of its preferential phase separation into rocksalt ScN and wurtzite AlN phases. A typical method to create these materials is reactive dual-target DC magnetron sputtering. As the scandium content increases, the competing rocksalt phase is more likely to form. Strict process control is necessary and difficult to ensure that the wurtzite forms instead, and that it is properly aligned.

It is believed that tensile biaxial strain helps stabilize the wurtzite formation and reduces rocksalt formation of Al₁₋ₓScₓN layers, and that it helps enhance the electromagnetic coupling coefficient kₜ_{²} by decreasing bond stiffness. While controlling the strain state during a deposition process can aid somewhat in preventing rocksalt formation, the deposited AlScN layer will still attempt to form its equilibrium lattice constant during deposition and annealing steps. Hence, there remains a need for a process to ensure that tensile biaxial stress remains after deposition and processing steps. There also remains a need for engineering a strain state in piezoelectric layers, where that strain state will remain even if the piezoelectric layer is not in contact with portions of the substrate, such as for example when there is an air gap or a Bragg reflector between the piezoelectric layer and the substrate.

### SUMMARY

Disclosed are methods of fabrication and related piezoelectric devices which overcome the current drawbacks noted above. The devices disclosed herein comprise a piezoelectric layer with an induced compressive strain along a z-axis. The methods include formation of a stress layer on a bottom side of a wafer substrate, after deposition of the piezoelectric layer. Stress layer removal results in an induced compressive strain along the z-axis which increases the electromechanical coupling coefficient, and thereby piezoelectric performance. Related devices are also disclosed, including bulk acoustic wave (BAW) thin film resonators (FBAR), which are fabricated in accordance with embodiments disclosed herein.

### Selected Definitions and Nomenclature

As used herein “wurtzite” phase crystal structure refers to a structure in which the anions have approximately a hexagonal close packed arrangement with the cations occupying one type of tetrahedral hole. Examples of this structure are found in ZnS, ZnO, AlN, SiC, and NH₄F. A wurtzite structure of AlN is shown in FIG. 1.

As used herein, references to z-axis refer to the wurtzite crystallographic “c” axis (example of wurtzite AlN is shown in FIG. 1, with the x, y, z axes).

As used herein, the term “induced” as it relates to compressive strain (i.e. “induced compressive strain”) refers to the purposeful modulation of a compressive strain state along an axis of a crystal lattice, after a deposition process. This is in contrast to a compressive strain which may occur due to process parameters during deposition of a piezoelectric material. The term “induced” therefore only references modulation of a compressive state which is achieved in fabrication steps which occur after deposition of a thin film layer has concluded.

The term “thermal expansion coefficient”, or “coefficient of thermal expansion” or “CTE”, refer to the same parameter, and may be used interchangeably throughout the disclosure. The terms refer to a measure of a particular material's expansion or contraction per degree of temperature.

As used herein a “bottom side” of a semiconductor substrate refers to a side of the substrate which is opposite the side of semiconductor layer deposition. A “top side” refers to the general side of the substrate wherein the semiconductor layer deposition typically occurs.

The term “about” is used in conjunction with numeric values to include normal variations in measurements as expected by persons skilled in the art, and is understood to have the same meaning as “approximately” and to cover a typical margin of error, such as ±15%, ±10%, ±5%, ±1%, ±0.5%, or even ±0.1% of the stated value. The term “about” also encompasses amounts that differ due to different equilibrium conditions for a composition resulting from a particular initial composition. Whether or not modified by the term “about,” the claims include equivalents to the quantities.

It should be noted that, as used in this specification and the appended claims, the singular forms “a,” “an,” and “the” include plural referents unless the content clearly dictates otherwise. Thus, for example, reference to a composition containing “a compound” includes having two or more compounds that are either the same or different from each other. It should also be noted that the term “or” is generally employed in its sense including “and/or” unless the content clearly dictates otherwise. As used herein, “and/or” refers to and encompasses any and all possible combinations of one or more of the associated listed items, as well as the lack of combinations when interpreted in the alternative (“or”).

In the interest of brevity and conciseness, any ranges of values set forth in this specification contemplate all values within the range and are to be construed as support for claims reciting any sub-ranges having endpoints which are real number values within the specified range in question. By way of a hypothetical illustrative example, a disclosure in this specification of a range of from 1 to 5 shall be considered to support claims to any of the following ranges: 1-5; 1-4; 1-3; 1-2; 2-5; 2-4; 2-3; 3-5; 3-4; and 4-5.

The term “substantially” is utilized herein to represent the inherent degree of uncertainty that can be attributed to any quantitative comparison, value, measurement, or other representation. The term “substantially” is also utilized herein to represent the degree by which a quantitative representation can vary from a stated reference without resulting in a change in the basic function of the subject matter at issue.

The term “comprise,” “comprises,” and “comprising” as used herein, specify the presence of the stated features, integers, steps, operations, elements, and/or components, but do not preclude the presence or addition of one or more other features, integers, steps, operations, elements, components, and/or groups thereof.

As used herein, the transitional phrase “consisting essentially of” means that the scope of a claim is to be interpreted to encompass the specified materials or steps recited in the claim and those that do not materially affect the basic and novel characteristic(s) of the claimed invention. Thus, the term “consisting essentially of” when used in a claim of this invention is not intended to be interpreted to be equivalent to “comprising.”

As used herein, the terms “increase,” “increasing,” “increased,” “enhance,” “enhanced,” “enhancing,” and “enhancement” (and grammatical variations thereof) describe an elevation of at least about 1%, 5%, 10%, 15%, 25%, 50%, 75%, 100%, 150%, 200%, 300%, 400%, 500% or more as compared to a control.

As used herein, the terms “reduce,” “reduced,” “reducing,” “reduction,” “diminish,” and “decrease” (and grammatical variations thereof), describe, for example, a decrease of at least about 1%, 5%, 10%, 15%, 20%, 25%, 35%, 50%, 75%, 80%, 85%, 90%, 95%, 97%, 98%, 99%, or 100% as compared to a control. In particular embodiments, the reduction can result in no or essentially no (i.e., an insignificant amount, e.g., less than about 10% or even 5% or even 1%) detectable activity or amount.

The terms “preferred” and “preferably” refer to embodiments that may afford certain benefits, under certain circumstances. However, other embodiments may also be preferred, under the same or other circumstances. Furthermore, the recitation of one or more preferred embodiments does not imply that other embodiments are not useful, and is not intended to exclude other embodiments from the scope of the present disclosure.

The terms “over,” “under,” “between,” and “on” as used herein refer to a relative position of one component or material with respect to other components or materials where such physical relationships are noteworthy. For example in the context of materials, one material or material disposed over or under another may be directly in contact or may have one or more intervening materials. Moreover, one material disposed between two materials or materials may be directly in contact with the two layers or may have one or more intervening layers. In contrast, a first material or material “on” a second material or material is in direct contact with that second material/material. Similar distinctions are to be made in the context of component assemblies.

As used throughout this description, and in the claims, a list of items joined by the term “at least one of” or “one or more of” can mean any combination of the listed terms. For example, the phrase “at least one of X, Y or Z” can mean X; Y; Z; X and Y; X and Z; Y and Z; or X, Y and Z

### BRIEF DESCRIPTION OF THE DRAWINGS

FIG. 1 shows a schematic of wurtzite crystal structure of AlN unit cell and corresponding x, y, z axes of the cell.

FIG. 2A depicts a cross-sectional view of a piezoelectric device deposition process.

FIG. 2B depicts a cross-sectional view of a piezoelectric device deformation bowing after stress layer addition, in accordance with embodiments disclosed herein.

FIG. 3 depicts a cross-sectional view of a piezoelectric device having a piezoelectric layer deposited thereon, in accordance with embodiments disclosed herein.

FIG. 4 depicts a cross-sectional view of a piezoelectric device having the stress layer removed, in accordance with embodiments disclosed herein.

FIG. 5 shows graphical results of biaxial strain in four wurtzites Al₁₋ₓScₓN and Zn₁₋ₓMgₓO.

FIG. 6 shows graphical results comparison of uniaxial (z) and biaxial (x+y) and triaxial strain in AlN and ZnO.

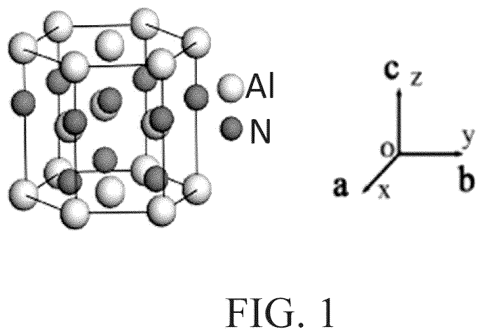

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

Described herein are piezoelectric devices and methods of fabricating said devices. The methods described here result in devices having compressive strain along the z-axis direction, which thereby improves the device's piezoelectric properties.

In one embodiment, a method of inducing compressive strain in a piezoelectric device 10 is disclosed. The method comprises providing a substrate material 100, depositing at least one seed layer 200 on a top surface of the substrate material and depositing a stress layer 300 on a bottom surface of the substrate material. Thereafter a piezoelectric layer 400 is deposited on the at least one seed layer 200. The stress layer 300 is then removed. The stress layer 300 induces a z-axis compressive strain in the piezoelectric layer 400, which remains even after removal of the stress layer. It is believed that this induced compressive strain along the z-axis contributes to an increase in the electromechanical coupling constant, kₜ_{²}, of the piezoelectric layer material.

A substrate material to be used can be a ceramic material such as alumina, sapphire, GaN, glass or a silicon, Si(100) or Si(111) substrate. Silicon wafers are the most common substrate for BAW devices due to their scalability towards mass manufacturing and compatibility with various manufacturing process steps.

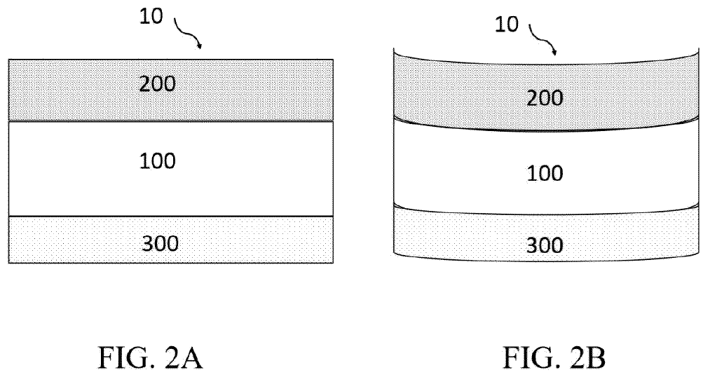

As can be seen in FIG. 2A, in one embodiment a seed layer 200 is deposited on a top surface of the substrate material 100. The seed layer can also sometimes be referred to as a nucleation layer or a buffer layer. It can also function simultaneously as an electrode. In one embodiment the deposition of seed layer 200 is an optional step. The purpose of this layer is to provide improved crystal growth and enhance crystal orientation for deposition of the functional piezoelectric layer. It is to be understood that the seed layer deposition, while referenced as a single step for purposes of simplicity and brevity, it can include multiple seed layers deposited in succession. In one embodiment, the seed layer comprises AlN and is deposited at a film thickness of about 10-100 nm. In other embodiments, seed layer materials can include at least one of Ti, SiNₓ, SiOₓ, SiCₓ, Si, Al, Mo, W, Pt, Au, REOs (i. e. rare earth oxides). The seed layer deposition step can be accomplished via metal-organic chemical vapor deposition (MO-CVD), pulsed laser deposition, reactive sputtering, or other appropriate methods which are known to those skilled in the art. In one example, an AlN seed layer can be deposited on a Si substrate, using an Al target in a sputtering chamber, at a temperature of 350° C. Base pressure of the sputtering chamber during deposition can be about 2×10⁻³ mbar. Gas flows introduced during sputtering can be for example, 10 sccm of Ar and 40 sccm of N₂.

In one embodiment, where the piezoelectric device is a solidly mounted resonator (SMR), the seed layer can include a Bragg reflector. An acoustic Bragg reflector consists of a multilayer stack of alternating layers of two different acoustic materials, having high and low acoustic impedance.

As shown in FIG. 2A, on a bottom side of the substrate material 100, a stress layer 300 is deposited. This step occurs before or after the optional seed layer 200 is deposited. The stress layer 300 will have a thickness about 1-30 microns. In one embodiment, the stress layer comprises SiOₓ wherein 1<x<3, SiN_{y} wherein 0.5<y<2, or Si_{1-z}Ge_{z} wherein 0<z<1. The stress layer 300 is designed to create a bowing of the device 10, which can be seen in FIG. 2B. This deformation of the device 10 should be in the range of about 10-200 microns, such that the substrate layer 100 is curved upwards and the top surface of the substrate layer/or seed layer are under compressive x,y stress. In one embodiment, this can be achieved by choosing the stress layer 300 to have a lower thermal expansion coefficient than the silicon substrate layer 100 upon which it is deposited, and depositing the stress layer 300 at an elevated temperature. This means that during post-deposition cooling of the device 10, the stress layer 300 will contract less than the substrate layer 100. During the cool down process, biaxial x, y stress will cause the bowing of the substrate layer, and of the device 10, which now includes the stress layer 300, seen in FIG. 2A. The stress layer can be deposited via PVD, MOCVD, PECVD, or other known deposition methods. The deposition temperature, the material to be deposited, and the thickness of the film to be deposited, will govern which deposition methods are utilized for forming the various layers of the devices disclosed herein. The deposition temperature for this step is in the range of 150°-900° C., and preferably about 300° C.-650° C.

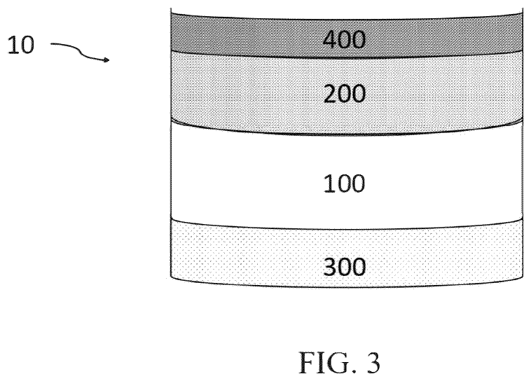

After deposition of the stress layer 300, the piezoelectric layer 400 is deposited onto the at least one seed layer 200, or in embodiments with no seed layer, the deposition would occur on the substrate 100 or other buffer layers or electrode layer (not shown in FIG. 3). The thickness of this layer will be about 50-1000 nm. In one embodiment, the deposition of the piezoelectric layer 400 is carried out by a sputtering process. Sputter deposition of this layer will generally result in compressive x, y stress, so the deposition process should be carefully controlled to ensure wurtzite formation and minimize rocksalt formation. In certain sputtering processes, typical values use a substrate temperature 350-450° C. with deposition under N₂/Ar gas of 1-10 μbar with flow rates 10-60 sccm each; sputtering power and target-substrate distance can be further optimized based on the sputtering devices used. The material for this layer includes at least one of Al₁₋ₓMₓN, where M=Sc, Y, Yb, Cr, B or any metal or transition or rare-earth element, or a combination thereof, wherein 0.1<x<0.7. It can alternatively be comprised of Zn₁₋ₓMₓO, where M can be Mg or any other metallic or rare-earth element and where 0.1<x<0.4. In one embodiment, the piezoelectric layer material comprises Al₁₋ₓScₓN, wherein 0<x<0.5.

Once deposited, the layer 400 will be under tensile strain along the z-axis, due to the bowing deformation effect that is provided by the stress layer 300. The stress layer 300 will be under compressive strain along the z-axis at this time. Once the stress layer is removed (in later process steps), the bowing effect will be reversed and the piezoelectric layer 400 will be under compressive strain along the z-axis.

Although not shown in the figures, an optional capping layer can be deposited onto piezoelectric layer 400. The capping layer will have a larger lattice constant than the layer 400. In some embodiments, the capping layer comprises Al₁₋ₓ(In,Ga)ₓN where 0<x<1, or preferably 0.2<x<0.6. The larger lattice constant will ensure that the device 10 is under tensile x, y stress on the top portion, inducing a compressive strain on the z-axis through the Poisson effect. In alternate embodiments, a capping layer that has a smaller CTE than the piezoelectric layer can be deposited at elevated temperatures. When this capping layer is cooled down, the capping layer will contract less than the piezoelectric layer, inducing a biaxial x, y tensile strain in the piezoelectric layer. Similar to the previous embodiment, this x,y tensile strain induces a compressive z-axis strain due to the Poisson effect.

In some embodiments, an optional annealing step is conducted on device 10, after deposition of the layer 400. Annealing is carried out at elevated temperatures of 900° C. or greater, to relieve compressive x,y stress formed during deposition steps. This can also improve crystallization and/or orientation of the piezoelectric layer 400. In some embodiments, the annealing step can further incorporate an applied electric field (AC or DC). The applied electric field, during the annealing process, is believed to improve crystallinity of the piezoelectric layer 400.

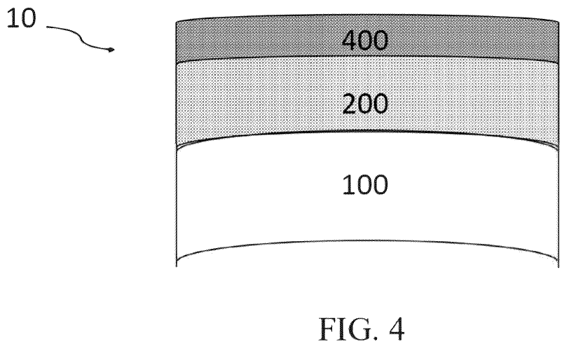

As depicted in FIG. 4, the stress layer 300 is then removed from the bottom of device 10. Removal of this layer can be carried about through a chemical or mechanical process, such as etching for example. This removal step shifts the x, y stress of the functional layer towards tensile strain, ensuring an overall tensile x, y strain, as compared to the deposition conditions. It is notable in FIG. 4, that now the device 10 has a bowing deformation opposite of that during the deposition process steps. This removal shifts the piezoelectric layer 400 to experience an induced compressive strain along the z-axis due to the Poisson effect. The targeted compressive strain on the piezoelectric layer 400 along the z-axis will be in the range of about 0.25-3.0%, or preferably 0.5-1.0%.

In further steps, portions of the substrate material 100 can be removed (not shown), along with portions of the optional seed layer 200. This removal step and geometry will depend on the type of piezoelectric device being fabricated. In some embodiments, the piezoelectric device is an FBAR membrane resonator, in which case some portion of the substrate material 100, can be removed to fabricate this device. In other embodiments, the device is an air gap FBAR, which will require removal of portions of the seed layer. These various types of FBAR devices and their geometries are known to those skilled in the art, therefore this disclosure need not provide details on the various fabrication methods of these devices. In one embodiment, the piezoelectric device is a solidly mounted resonator (SMR), having an acoustic mirror (Bragg reflector).

In other embodiments, the resonators disclosed herein, having piezoelectric material layers with the induced compressive state along the z-axis, may be incorporated in electrical filter devices, including a bandpass or bandstop filter. In one embodiment, an electrical filter is disclosed which incorporates a film bulk acoustic resonator (FBAR) device. The FBAR devices comprises a substrate material, a piezoelectric layer having an induced compressive strain along a z-axis of about 0.25-3.0% and an electromechanical coupling constant, kₜ_{²} of about 0.05-0.6. It further comprises first electrode on a top surface of the piezoelectric layer and a second electrode on a bottom surface of the piezoelectric layer. The induced compressive strain along the z-axis of the piezoelectric layer is provided by a stress layer during the device's deposition process, in accordance with various embodiments disclosed above.

As previously noted, the purpose of the present invention is to improve the performance of a piezoelectric crystalline resonator. The piezoelectric tensor and electromechanical coupling constant can be computed with first principles calculations. The calculations shown here use density functional theory (DFT) as implemented in the Vienna ab-initio Simulation Package (VASP) with the VASP-provided PBE exchange-correlation functional and PAW pseudopotentials, as is standard in many ab-initio calculations. The piezoelectric properties are computed with the density functional perturbation theory (DFPT) implementation within VASP. For simplicity, the values shown are at minimal supercells of undoped AlN (or ZnO) and 25% doping, although previous publications have shown that most piezoelectric trends are comparable between 25% doping and other doping levels. We can compute the piezoelectric properties (piezoelectric constant, dielectric constant, and stiffness) as a function of strain, by straining the unit cell and allowing the internal degrees of freedom to relax. We consider the following three strains:

Triaxial strain, whereby x, y, and z directions of the lattice are strained by the same value ε. This can be realized by (or is reasonably close to) unconstrained thermal expansion or hydrostatic compression.

Biaxial epitaxial strain, whereby x and y are strained by the same value ε, and z relaxes in the opposite direction due to the Poisson effect. This can alternatively be implemented by fixing z according to the measured or calculated Poisson ratio of the material. This can be realized by mismatch of coefficients of thermal expansion between different layers, or deposition on a strained substrate, or the methods previously described in this disclosure. It can also be realized by a lattice-mismatched cap wafer, which will strain x and y accordingly.

Uniaxial strain, whereby z is strained by a value &, and the x and y strains emerge from the Poisson effect. In principle, this can be realized by imposing a pressure upon the two electrodes of the device and thereby compressive stress upon the intermediate piezoelectric layer.

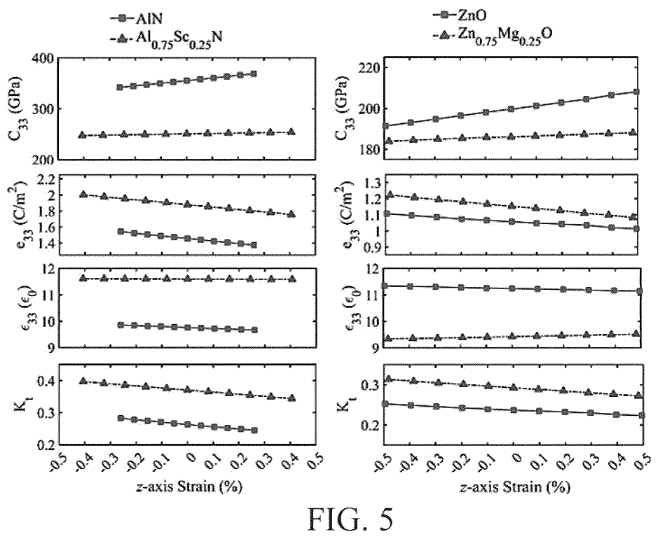

Referring to the graphs shown in FIG. 5, biaxial applied strain in four wurtzites of interest is shown. The strain is applied biaxially with x and y strained in one direction and z correspondingly in the opposite direction due to the Poisson effect. It can be seen by these computations that compressive strain along the z axis (or epitaxial x and y tensile strain) in all of the disclosed materials (AlN, ZnO etc.) improves the electromechanical coupling constant kₜ_{²}, both through increasing the piezoelectric constant e₃₃ and (especially in ZnO) decreasing the stiffness C₃₃.

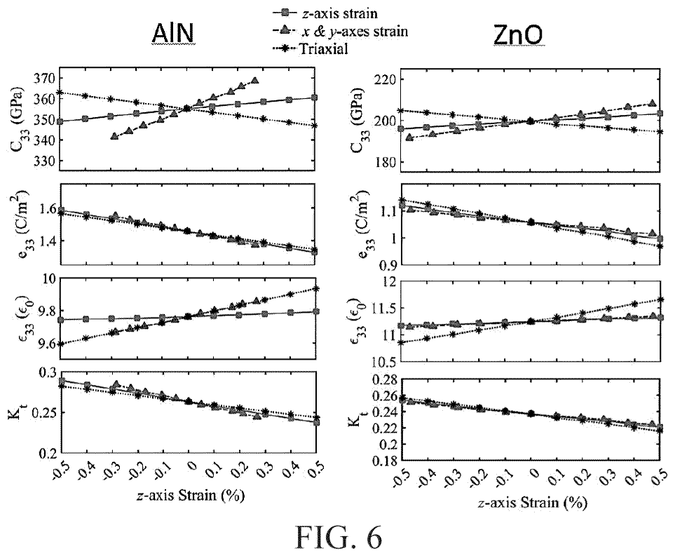

FIG. 6 shows comparisons of uniaxial (z), biaxial (x+y), and triaxial strain in AlN and ZnO. The overall effect suggests that regardless of the type of strain—whether tensile strain of x+y and thereby compressive strain of z, or triaxial compressive strain—the kₜ_{²} value is enhanced by compressive strain along the z axis.

In further embodiments, a film bulk acoustic resonator (FBAR) device, is disclosed, in accordance with the piezoelectric device fabrication methods disclosed above. The FBAR device comprises a piezoelectric layer having an induced z-axis compressive strain, a first electrode on a top surface of the piezoelectric layer; a second electrode on a bottom surface of the piezoelectric layer; and a substrate material. In this embodiment, the induced compressive strain along the z-axis of the piezoelectric layer is provided by a stress or cap layer during the device's fabrication steps, as disclosed in the outlined method steps disclosed in prior embodiments (not repeated here for brevity). It is to be understood that the induced strain state along the z-axis which is incorporated in the embodiment of the FBAR devices, is achieved through the method/fabrication steps outlined in detail in the various embodiments above.

In some embodiments, at least some portion of the piezoelectric layer is not attached to the substrate material. This is the case for example in air gap FBAR devices. In other embodiments, the film bulk acoustic resonator is a membrane FBAR, or a solidly mounted resonator (SMR).

The piezoelectric layer is comprised of Al₁₋ₓMₓN, where M=Sc, Y, Yb, Cr, B or any metal, or transition or rare-earth element or a combination thereof. It can alternatively be comprised of Zn₁₋ₓMₓO, where M can be Mg or any other metallic or rare-earth element and where 0.1<x<0.7. In one embodiment, the piezoelectric layer comprises Al₁₋ₓScₓN, wherein 0<x<0.5.

In some embodiments, the piezoelectric layer has an electromechanical coupling constant, kₜ_{²}, of about 0.05-0.6. In further embodiments it is about 0.12 and 0.3. In some embodiments, the piezoelectric layer has a piezoelectric constant e₃₃ of 1.0-4.0 C/m². In some embodiments, the piezoelectric layer has a stiffness C₃₃ of 150-450 GPa.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

What is claimed is:

1. A method of inducing compressive strain in a piezoelectric device, comprising:
providing a substrate material;
depositing at least one seed layer on a top surface of the substrate material;
depositing a stress layer on a bottom surface of the substrate material;
depositing a piezoelectric layer on the at least one seed layer;
removing the stress layer;
wherein the deposition and removal of the stress layer induces compressive strain along a z-axis of the piezoelectric layer.

2. The method of claim 1, wherein the induced compressive strain along the z-axis on the piezoelectric layer is about 0.25-3.0%.

3. The method of claim 1, wherein the stress layer comprises SiOₓ wherein 1<x<3, SiN_{y} wherein 0.5<y<2, or Si_{1-z}Ge_{z} wherein 0<z<1.

4. The method of claim 1, wherein depositing a stress layer causes bowing of the substrate material and/or the at least one seed layer of about 10-200 microns.

5. The method of claim 1, wherein the piezoelectric layer comprises Al₁₋ₓMₓN, where M=at least one of Sc, Y, Yb, Cr, B, wherein 0<x<0.7, or Zn₁₋ₓMₓO, wherein M is Mg and wherein 0.1<x<0.4.

6. The method of claim 1, wherein the piezoelectric layer comprises Al₁₋ₓScₓN, wherein 0<x<0.5.

7. The method of claim 1, further comprising depositing a capping layer comprising Al₁₋ₓ(In,Ga)ₓN wherein 0<x<1 on the piezoelectric layer.

8. The method of claim 7, wherein the capping layer has a greater lattice constant than the piezoelectric layer.

9. The method of claim 1, further comprising annealing the piezoelectric layer at a temperature greater than about 900° C.

10. The method of claim 9, wherein during the annealing step, an electric field is applied.

11. The method of claim 1, further comprising removing the substrate material and/or the at least one seed layer.

12. The method of claim 1, wherein the piezoelectric device is a membrane film bulk acoustic resonator (FBAR), an air gap FBAR, or a solidly mounted resonator (SMR).

13. A film bulk acoustic resonator (FBAR) device, comprising:
a substrate material;
a piezoelectric layer having an induced compressive strain along a z-axis;
a first electrode on a top surface of the piezoelectric layer; and
a second electrode on a bottom surface of the piezoelectric layer,
wherein the induced compressive strain along the z-axis of the piezoelectric layer is provided by a stress layer during the device's deposition process.

14. The device of claim 12, wherein at least some portion of the piezoelectric layer is not attached to the substrate material.

15. The device of claim 14, wherein the induced compressive strain along the z-axis in the piezoelectric layer remains after portions of the substrate material are removed.

16. The method of claim 1, wherein the piezoelectric layer comprises Al₁₋ₓMₓN, where M=at least one of Sc, Y, Yb, Cr, B, wherein 0<x<0.7, or Zn₁₋ₓMₓO, wherein M is Mg and wherein 0.1<x<0.4.

17. The device of claim 16, wherein the piezoelectric layer comprises Al₁₋ₓScₓN, wherein 0<x<0.5.

18. The device of claim 12, wherein the piezoelectric layer has an electromechanical coupling constant, kₜ_{²}, wherein kₜ_{²} is about 0.05-0.6.

19. The device of claim 12, wherein the device is a membrane film bulk acoustic resonator (FBAR), or an air gap FBAR.

20. An electrical filter comprising;
a film bulk acoustic resonator (FBAR) device, which comprises:
a substrate material;
a piezoelectric layer having an induced compressive strain along a z-axis of about 0.25-3.0% and an electromechanical coupling constant, kₜ_{²} of about 0.05-0.6;
a first electrode on a top surface of the piezoelectric layer; and
a second electrode on a bottom surface of the piezoelectric layer,
wherein the induced compressive strain along the z-axis of the piezoelectric layer is provided by a stress layer during the device's deposition process.
